(19) United States
(12) Patent Application Publication
(10) Pub. No.: US 2026/0047399 A1
(43) Pub. Date: Feb. 12, 2026

(54) SEMICONDUCTOR DEVICE

(71) Applicant: Samsung Electronics Co., Ltd., Suwon-si (KR)

(72) Inventors: Junyun KWEON, Suwon-si (KR); Wooju KIM, Suwon-si (KR); Je-Sung KIM, Suwon-si (KR); Dayoung CHO, Suwon-si (KR); Minhaeng HEO, Suwon-si (KR); Jinwook HONG, Suwon-si (KR)

(73) Assignee: Samsung Electronics Co., Ltd., Suwon-si (KR)

(21) Appl. No.: 19/043,634

(22) Filed: Feb. 3, 2025

(30) Foreign Application Priority Data
Aug. 8, 2024 (KR) 10-2024-0106034

(51) Int. Cl. H01L 21/66; H01L 23/00; H01L 23/29; H01L 23/31

(52) U.S. Cl. CPC H01L 22/32; H01L 23/3192; H01L 24/05; H01L 23/293; H01L 24/03; H01L 2224/0362; H01L 2224/03622; H01L 2224/05567; H01L 2224/056

(57) ABSTRACT

Some example embodiments are directed to a semiconductor device including a substrate including a chip region and a peripheral region, a circuit wiring layer on the chip region of the substrate, an interlayer insulating layer on the chip region of the substrate covering the circuit wiring layer, and extending on the peripheral region of the substrate, a chip pad on the interlayer insulating layer on the chip region, and connected to the circuit wiring layer, and a test pad on the interlayer insulating layer on the peripheral region. A thickness of the test pad is less than a thickness of the chip pad in a direction vertical to an upper surface of the substrate.

### CROSS-REFERENCE TO RELATED APPLICATIONS

This U.S. non-provisional patent application claims priority under 35 U.S.C. § 119 to Korean Patent Application No. 10-2024-0106034, filed on Aug. 8, 2024, the entire contents of which are hereby incorporated by reference.

### BACKGROUND

Example embodiments relate to a semiconductor device including a test element group (TEG) disposed on a scribe lane.

Semiconductor elements (for example, a transistor, a capacitor, a resistor, and an inductor) that constitute a semiconductor integrated circuit may be formed by performing, on a semiconductor substrate, a series of processes including a deposition process for depositing a thin-film, a photo lithography process and an etching process for patterning the thin-film, and the like. In order to confirm whether or not the semiconductor elements are formed in accordance with the design of the semiconductor integrated circuit, the semiconductor elements may be inspected for a defect after each process, and parameter characteristics of the semiconductor elements may be evaluated.

In order to evaluate the characteristics of the semiconductor elements, measuring elements or test elements may be formed together with the semiconductor elements. The semiconductor substrate may include chip regions on which the integrated circuit is formed, and a scribe lane between the chip regions, and the test elements may be formed on the scribe lane of the semiconductor substrate.

### SUMMARY

Example embodiments provide a semiconductor device configured to reduce or minimize a defect generated by a sawing process for cutting a semiconductor substrate, and a method for manufacturing the same.

Example embodiments also provide a semiconductor device configured to improve or increase bonding strengths of chip pads of a semiconductor chip, and a method for manufacturing the same.

According to some example embodiments of the inventive concepts, a semiconductor device may include a substrate including a chip region and a peripheral region, a circuit wiring layer on the chip region of the substrate, an interlayer insulating layer covering the circuit wiring layer on the chip region of the substrate, and extending on the peripheral region of the substrate, a chip pad disposed on the interlayer insulating layer on the chip region and connected to the circuit wiring layer, and a test pad disposed on the interlayer insulating layer on the peripheral region. A thickness of the test pad is less than a thickness of the chip pad in a direction vertical to an upper surface of the substrate.

According to some example embodiments of the inventive concepts, a semiconductor device may include a substrate including a chip region and a peripheral region, an integrated circuit layer on the chip region of the substrate, a circuit wiring layer disposed on the chip region of the substrate and on the integrated circuit layer, and connected to the integrated circuit layer, an interlayer insulating layer covering the integrated circuit layer and the circuit wiring layer on the chip region of the substrate and extending on the peripheral region of the substrate, a plurality of chip pads disposed on the interlayer insulating layer on the chip region, and spaced apart from each other in a direction parallel to an upper surface of the substrate, and a test pad disposed on the interlayer insulating layer on the peripheral region. The plurality of chip pads are electrically connected to the integrated circuit layer through the circuit wiring layer, and a thickness of the test pad is less than a thickness of each of the plurality of chip pads in a direction vertical to the upper surface of the substrate.

According to some example embodiments of the inventive concepts, a semiconductor device may include a substrate including a plurality of chip regions and a scribe lane therebetween, a circuit wiring layer disposed on each of the plurality of chip regions, an interlayer insulating layer covering the circuit wiring layer on each of the plurality of chip regions and extending on the scribe lane, a plurality of chip pads disposed on the interlayer insulating layer on each of the plurality of chip regions and spaced apart from each other in a direction parallel to an upper surface of the substrate, and a test pad disposed on the interlayer insulating layer on the scribe lane. The plurality of chip pads are electrically connected to the circuit wiring layer, and a thickness of the test pad is less than a thickness of each chip pad of the plurality of chip pads in a direction vertical to the upper surface of the substrate.

### BRIEF DESCRIPTION OF THE DRAWINGS

The accompanying drawings are included to provide a further understanding of some example embodiments of the inventive concepts, and are incorporated in and constitute a part of this specification. The drawings illustrate some example embodiments of the inventive concepts and, together with the description, serve to explain principles of the inventive concepts. In the drawings:

FIG. 1 is a plan view of a semiconductor device according to some example embodiments of the inventive concepts.

FIG. 2 is an enlarged view illustrating a test element group TEG of FIG. 1.

FIG. 3 is a cross-sectional view taken along A-A′ of FIG. 1.

FIGS. 4, 5, 6, and 7 are diagrams illustrating a method for manufacturing a semiconductor device according to some example embodiments of the inventive concepts, and are cross-sectional views taken along A-A′ of FIG. 1.

FIG. 8 is a plan view illustrating a method for manufacturing a semiconductor device according to some example embodiments of the inventive concepts.

FIG. 9 is a cross-sectional view taken along A-A′ of FIG. 8.

FIG. 10 is a plan view of a semiconductor device according to some example embodiments of the inventive concepts.

FIG. 11 is a cross-sectional view taken along B-B′ of FIG. 10.

### DETAILED DESCRIPTION

Hereinafter, some example embodiments of the inventive concepts will be described in detail with reference to the accompanying drawings.

In the drawings, parts having no relationship with the description are omitted for clarity, and the same or similar constituent elements are indicated by the same reference numeral throughout the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

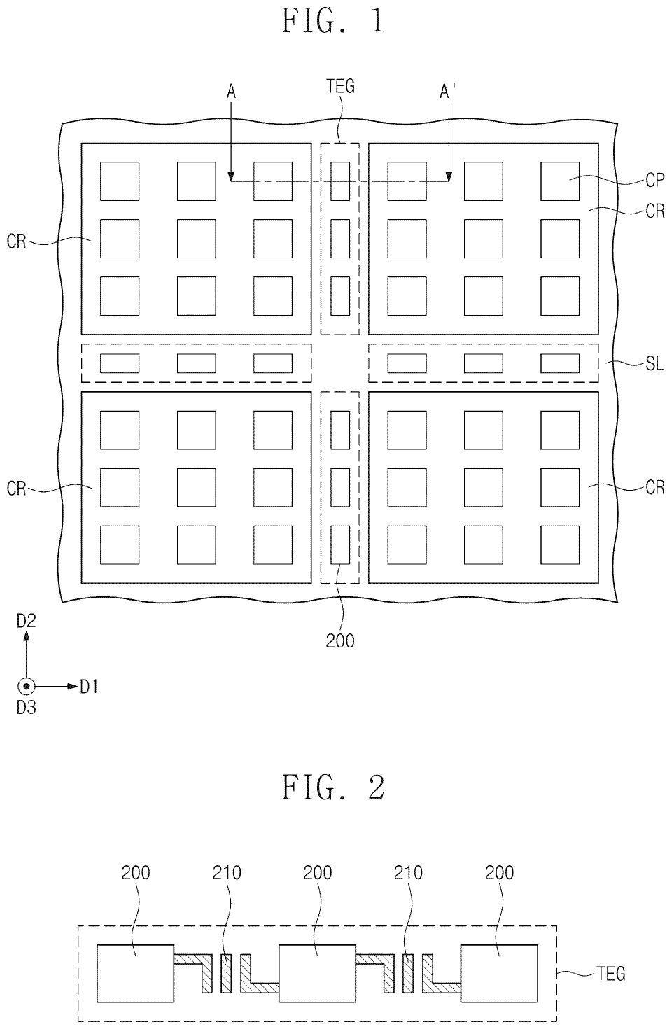

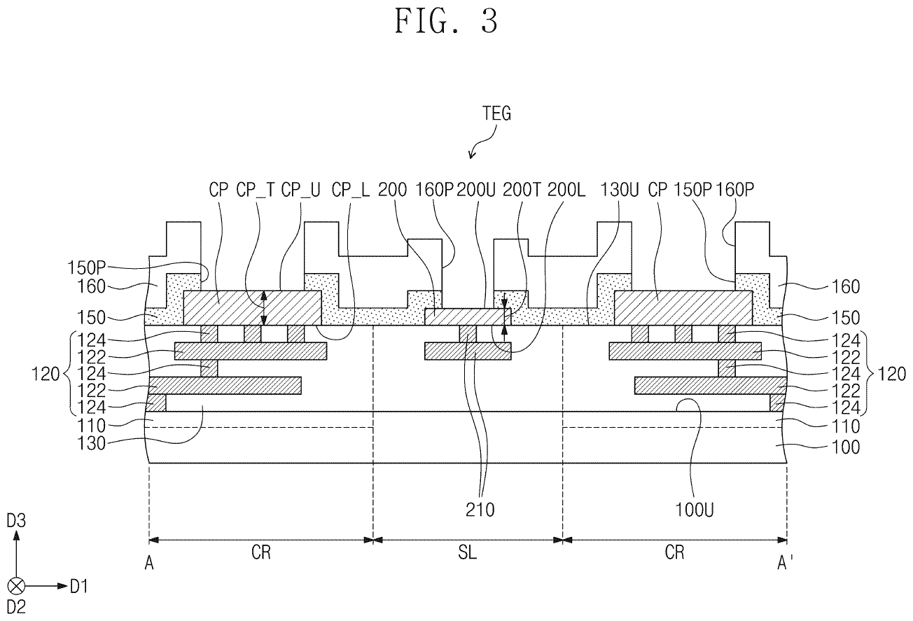

FIG. 1 is a plan view of a semiconductor device according to some example embodiments of the inventive concepts. FIG. 2 is an enlarged view illustrating a test element group TEG of FIG. 1. FIG. 3 is a cross-sectional view taken along A-A′ of FIG. 1.

Referring to FIGS. 1 to 3, a substrate 100 may include a plurality of chip regions CR and a scribe lane SL between the plurality of chip regions CR. The substrate 100 may be a semiconductor substrate, and for example, may be a silicon substrate or silicon-on-insulator (SOI) substrate. The plurality of chip regions CR may be spaced apart from each other along a first direction D1 and a second direction D2 both parallel to an upper surface 100U of the substrate 100, and crossing (e.g., perpendicular or transverse to) each other. The scribe lane SL may extend along the first direction D1 and the second direction D2, and may surround and/or separate each of the plurality of chip regions CR. In some example embodiments, the scribe lane SL may be referred to as a peripheral region.

An integrated circuit layer 110 may be disposed (or formed) on each of the plurality of chip regions CR of the substrate 100. The integrated circuit layer 110 may include semiconductor elements (for example, a transistor, a capacitor, a resistor, an inductor, and the like) that constitute an integrated circuit.

A circuit wiring layer 120 may be disposed on each of the plurality of chip regions CR of the substrate 100 and on the integrated circuit layer 110. The circuit wiring layer 120 may include multiple wiring lines 122 and multiple wiring contacts 124. The wiring lines 122 may form a stacked structure in which the wiring layers 122 may be spaced apart from each other along a third direction D3 vertical (or transverse) to the upper surface 100U of the substrate 100, and may be electrically connected to each other through one or more corresponding wiring contacts 124. Lowermost wiring lines 122 may be electrically connected to the integrated circuit layer 110 through corresponding wiring contacts 124. The wiring lines 122 and the wiring contacts 124 may include a conductive material, and for example, may include metal.

An interlayer insulating layer 130 may be disposed (or formed) on each of the plurality of chip regions CR of the substrate 100, and may at least partially cover the integrated circuit layer 110 and the circuit wiring layer 120. The interlayer insulating layer 130 may be disposed on the integrated circuit layer 110, and the wiring lines 122 and the wiring contacts 124 may be disposed in the interlayer insulating layer 130, and may be at least partially enclosed or encapsulated within the interlayer insulating layer 130. The interlayer insulating layer 130 may extend onto the scribe lane SL of the substrate 100, and may cover the upper surface 100U of the substrate 100. The interlayer insulating layer 130 may include a plurality of insulating films stacked on the substrate 100, and may include an insulating material (for example, silicon oxide, silicon nitride and/or silicon oxynitride).

A plurality of chip pads CP may be disposed on each of the plurality of chip regions CR of the substrate 100, and on the interlayer insulating layer 130. The plurality of chip pads CP may be spaced apart from each other on the interlayer insulating layer 130 along the first direction D1 and the second direction D2. The circuit wiring layer 120 may be disposed between the integrated circuit layer 110 and the plurality of chip pads CP, and may electrically connect the plurality of chip pads CP to the integrated circuit layer 110. The plurality of chip pads CP may be electrically connected to the integrated circuit layer 110 through the circuit wiring layer 120. For example, each of the plurality of chip pads CP may be electrically connected to uppermost wiring lines 122 among the multiple wiring lines 122 through corresponding wiring contacts 124 among the multiple wiring contacts 124. The wiring lines 122 may be electrically connected to each other through corresponding wiring contacts 124, and lowermost wiring lines 122 among the multiple wiring lines 122 may be electrically connected to the integrated circuit layer 110 through corresponding wiring contacts 124 among the multiple wiring contacts 124. The plurality of chip pads CP may include a conductive material, and for example, may include metal (for example, copper).

A test element group TEG may be disposed on the scribe lane SL of the substrate 100. The test element group TEG may include test patterns 210 and test pads 200 electrically connected to the test patterns 210. The test pads 200 may be disposed on the interlayer insulating layer 130 on the scribe lane SL, and may be horizontally spaced apart from each other along the first direction D1 or the second direction D2. Some of the test patterns 210 may be disposed on the interlayer insulating layer 130 on the scribe lane SL, and between the test pads 200. Other test patterns 210 may be disposed within the interlayer insulating layer 130 on the scribe lane SL. The test patterns 210 may be or include test elements for evaluating (e.g., analyzing or estimating) characteristics of the semiconductor elements (for example, a transistor, a capacitor, a resistor, an inductor, and the like). The test pads 200 may be electrically connected to the test patterns 210, and may be used to input/output an electrical signal to the test elements. The test pads 200 and the test patterns 210 may include a conductive material. For example, the test pads 200 may include metal (for example, copper).

The plurality of chip pads CP and the test pads 200 may include the same metal material. Lower surfaces CP_L of the plurality of chip pads CP and lower surfaces 200L of the test pads 200 may be in contact with (e.g., direct contact with) an upper surface 130U of the interlayer insulating layer 130. The lower surfaces CP_L of the plurality of chip pads CP and the lower surfaces 200L of the test pads 200 may be coplanar with the upper surface 130U of the interlayer insulating layer 130, and may be located at the same height (e.g., level or distance) from the substrate 100 (e.g., from an upper surface of the substrate 100). In the present specification, a height may be a distance measured from the upper surface 100U of the substrate 100 in the third direction D3. Upper surfaces 200U of the test pads 200 may be located at a lower height (e.g., level) from the substrate 100 than upper surfaces CP_U of the plurality of chip pads CP. In the present specification, the term ‘level’ may mean a vertical height and/or a distance from a reference location (e.g., the upper surface of the substrate 100, or the like) in a vertical direction (e.g., the third direction D3). A reference location may be understood to be a location that a level and/or relative level of an element is “based on” or is a level “from.” For example, when a first element is described herein to be at a level from a reference location that is higher than a second element, the first element may be further from the reference location in the vertical direction (e.g., third direction D3) than the second element. In another example, when a first element is described herein to be at a level from a reference location that is lower than a second element, the first element may be closer to reference location in the vertical direction (e.g., third direction D3) than the second element. In another example, when a first element is described herein to be at a same or substantially same level from a reference location as a second element, the first element may be equally distant from/close to the reference location in the vertical direction (e.g., third direction D3) as the second element.

Each of the plurality of chip pads CP and the test pads 200 may have a thickness along the third direction D3. A thickness 200T along the third direction D3 of each of the test pads 200 may be less than a thickness CP_T along the third direction D3 of each of the plurality of chip pads CP. The thickness CP_T of each of the plurality of chip pads CP may be equal to or greater than 2 μm (or about 2 μm). For example, the thickness CP_T of each of the plurality of chip pads CP may be 2 μm (or about 2 μm) to 5 μm (or about 5 μm). The thickness 200T of each of the test pads 200 may be less than 2 μm or about 2 μm. For example, the thickness 200T of each of the test pads 200 may be equal to or greater than 1000 Å (0.1 μm) (or about 0.1 μm) and/or less than 2 μm (or about 2 μm).

A passivation layer 150 may be disposed (or formed) on the plurality of chip regions CR and the scribe lane SL of the substrate 100, and on the interlayer insulating layer 130. The passivation layer 150 may be disposed on the interlayer insulating layer 130 between the plurality of chip pads CP, and may be interposed between the plurality of chip pads CP. The passivation layer 150 may be disposed on the interlayer insulating layer 130 between the test pads 200, and may be interposed between the test pads 200. The passivation layer 150 may be disposed on the interlayer insulating layer 130 between the plurality of chip pads CP and the test pads 200, and may be interposed between the plurality of chip pads CP and the test pads 200.

The passivation layer 150 may cover side surfaces of each of the plurality of chip pads CP, and may extend onto the upper surface CP_U of each of the plurality of chip pads CP. The passivation layer 150 may partially cover the upper surface CP_U of each of the plurality of chip pads CP. The passivation layer 150 may cover side surfaces of each of the test pads 200, and may extend onto the upper surface 200U of each of the test pads 200. The passivation layer 150 may partially cover the upper surface 200U of each of the test pads 200. The passivation layer 150 may have first openings 150P respectively exposing portions of the upper surfaces CP_U of the plurality of chip pads CP and the upper surfaces 200U of the test pads 200. The passivation layer 150 may include an insulating material, and for example, may include silicon oxide, silicon nitride, silicon oxynitride, a combination thereof and the like.

A protective layer 160 may be disposed (or formed) on the plurality of chip regions CR and the scribe lane SL of the substrate 100, and on the passivation layer 150. The protective layer 160 may be disposed (or formed) on the passivation layer 150 between the plurality of chip pads CP, and may be disposed on the passivation layer 150 between the test pads 200. The protective layer 160 may be disposed (or formed) on the passivation layer 150 between the plurality of chip pads CP and the test pads 200. The protective layer 160 may have second openings 160P respectively exposing portions of the upper surfaces CP_U of the plurality of chip pads CP and the upper surfaces 200U of the test pads 200. The second openings 160P may vertically (for example, in the third direction D3) respectively overlap the first openings 150P. Portions of the upper surfaces CP_U of the plurality of chip pads CP and the upper surfaces 200U of the test pads 200 may not be covered by the passivation layer 150 and the protective layer 160, and may be exposed through the first and second openings 150P and 160P. The protective layer 160 may include a polymer material, and for example, may include photosensitive polyimide.

When the thicknesses CP_T of the plurality of chip pads CP increase, bonding strengths between the plurality of chip pads CP and external connection terminals may be improved. When the thicknesses CP_T of the plurality of chip pads CP are increased so as to improve the bonding strengths of the plurality of chip pads CP, the thicknesses 200T of the test pads 200 may be also be increased.

According to some example embodiments of the inventive concepts, the test pads 200 on the scribe lane SL may be formed to have a lesser thickness than the plurality of chip pads CP on each of the plurality of chip regions CR. In some example embodiments, the plurality of chip pads CP may be relatively thicker (e.g., having a relatively greater thickness CP_T), and the bonding strengths between the plurality of chip pads CP and the external connection terminals may be improved, maximized or increased. In addition, or alternatively, the test pads 200 may have a relatively lesser thickness 200T (e.g., compared to thickness of the chip pads CP), and thus the test pads 200 may be cut with relative ease during the sawing process performed along the scribe lane SL.

Accordingly, defects occurring during the sawing process may be minimized, and a semiconductor device having improved bonding strengths of chip pads of a semiconductor chip may be obtained.

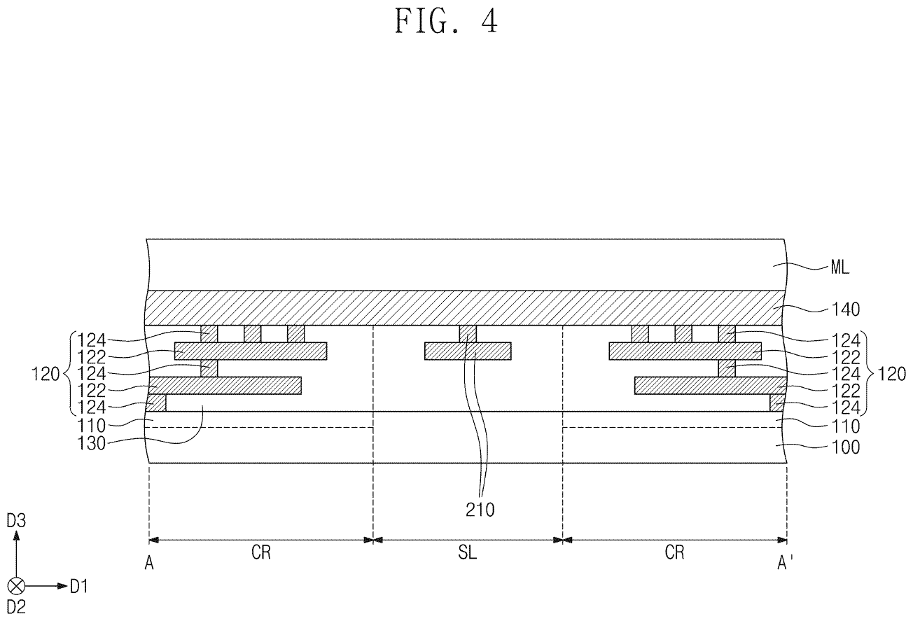

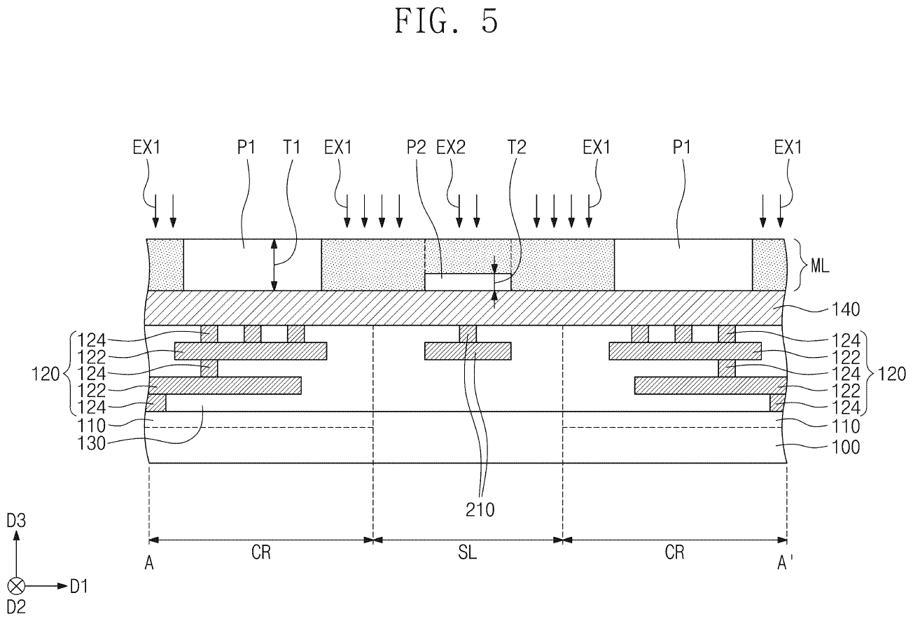

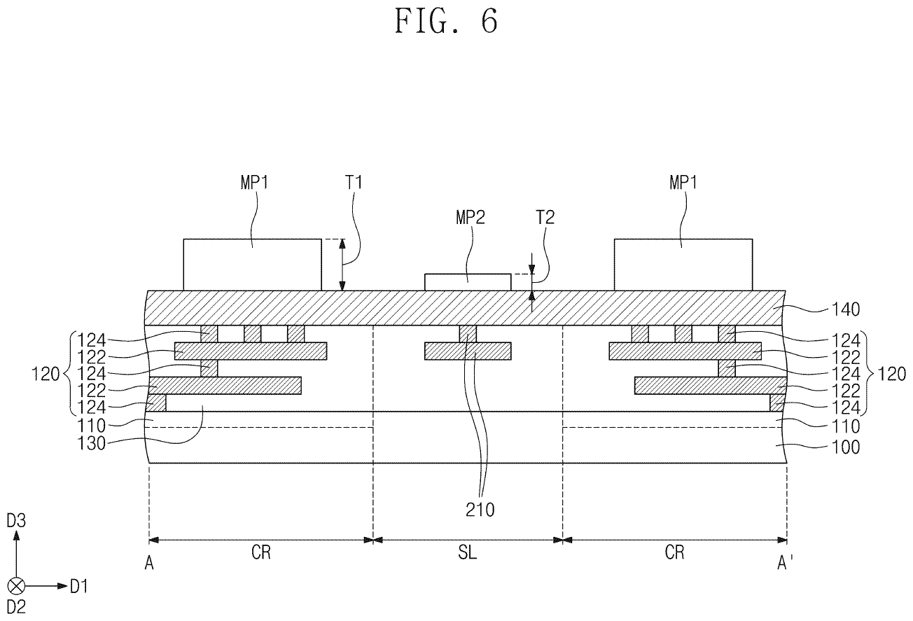

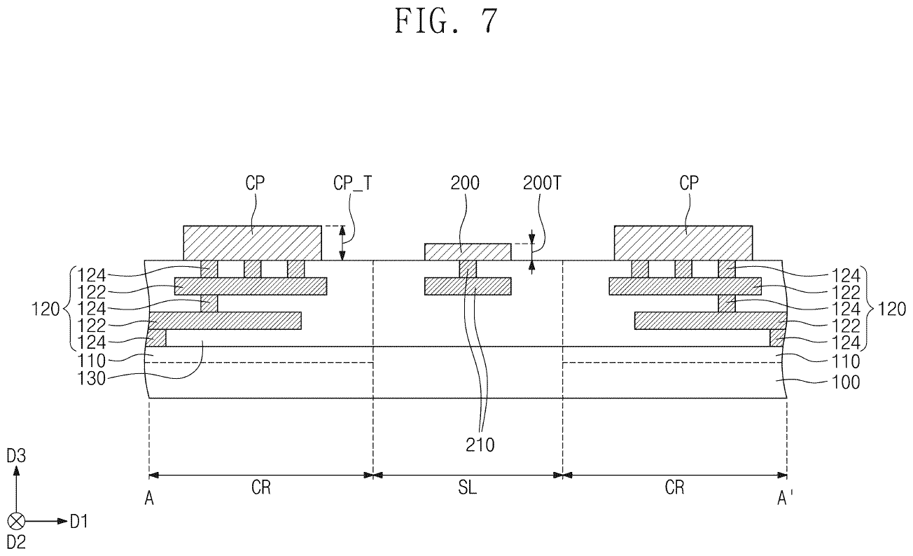

FIGS. 4 to 7 are diagrams illustrating a method for manufacturing a semiconductor device according to some example embodiments of the inventive concepts, and are cross-sectional views taken along A-A′ of FIG. 1. Elements of the semiconductor device illustrated in FIGS. 4-7 may be same as or similar in some respects to the elements of the semiconductor device of FIGS. 1-3, and therefore may be best understood with reference thereto where like numerals indicate like elements not described again in detail. It is understood that additional operations/processes can be provided before, during, and after the operations/processes in FIGS. 4-7, and some of the operations/processes described below can be replaced or eliminated, for additional embodiments of the method. The order of the operations/processes may be interchangeable, or two or more operations/processes can be performed simultaneously.

Referring to FIGS. 1, 2, and 4, the substrate 100 including the plurality of chip regions CR and the scribe lane SL between the plurality of chip regions CR may be provided.

The integrated circuit layer 110 may be formed on each of the plurality of chip regions CR of the substrate 100, and the circuit wiring layer 120 may be formed on each of the plurality of chip regions CR of the substrate 100, and on the integrated circuit layer 110. The interlayer insulating layer 130 may be formed on each of the plurality of chip regions CR of the substrate 100, and on the integrated circuit layer 110, and the circuit wiring layer 120 may be formed within the interlayer insulating layer 130. The circuit wiring layer 120 may include the wiring lines 122 and the wiring contacts 124. For example, the wiring lines 122 and the wiring contacts 124 may be formed by using a process of patterning a conductive film, or a damascene process that includes forming an empty region by patterning the interlayer insulating layer 130 and filling the empty region with a conductive film, or the like.

The interlayer insulating layer 130 may extend on the scribe lane SL of the substrate 100, and may cover the upper surface 100U of the substrate 100. The test patterns 210 may be formed in the interlayer insulating layer 130 on the scribe lane SL. The test patterns 210 may be formed by using the substantially same or similar process as the process of forming the wiring lines 122 and the wiring contacts 124.

A pad conductive film 140 may be formed on the plurality of chip regions CR and the scribe lane SL, and on the interlayer insulating layer 130. The pad conductive film 140 may include a conductive material, and for example, may include metal (for example, copper). The pad conductive film 140 may be formed by using a chemical vapor deposition process, a physical vapor deposition process, an electroplating process, or the like.

A mask film ML may be formed on the plurality of chip regions CR and the scribe lane SL, and on the pad conductive film 140. For example, the mask film ML may be a photoresist film.

Referring to FIGS. 1, 2, and 5, photo lithography processes EX1 and EX2 may be performed on the mask film ML. The mask film ML may include first parts P1 and second parts P2 formed by the photo lithography processes EX1 and EX2. The first parts P1 may be formed on each of the plurality of chip regions CR of the substrate 100, and may define regions in which the plurality of chip pads CP may be formed. The second parts P2 may be formed on the scribe lane SL of the substrate 100, and may define regions on which the test pads 200 may be formed.

A thickness T2 along the third direction D3 of each of the second parts P2 may be less than a thickness T1 along the third direction D3 of each of the first parts P1. In other words, the second parts P2 may be formed to have a thickness less than the first parts P1. For example, the first parts P1 and the second parts P2 may be formed by controlling exposure doses of the photo lithography processes EX1 and EX2. For example, forming the first parts P1 and the second parts P2 may include irradiating, with light at a first exposure dose EX1, the mask film ML except for regions on which the first parts P1 and the second parts P2 will be formed, and irradiating, with light at a second exposure dose EX2, the second parts P2. The second exposure dose EX2 may be different from the first exposure dose EX1, and for example, the second exposure dose EX2 may be smaller than the first exposure dose EX1.

Referring to FIGS. 1, 2, and 6, an exposed portion, which is exposed to the light (e.g., during photolithography), of the mask film ML may be removed by a developing process. Accordingly, first mask patterns MP1 and second mask patterns MP2 may be formed on the plurality of chip regions CR and the scribe lane SL, and on the pad conductive film 140. The first mask patterns MP1 may correspond to the first parts P1 of the mask film ML, and the second mask patterns MP2 may correspond to the second parts P2 of the mask film ML. The first mask patterns MP1 may be formed on each of the plurality of chip regions CR of the substrate 100, and may define regions on which the plurality of chip pads CP are formed. The second mask patterns MP2 may be formed on the scribe lane SL of the substrate 100, and may define regions on which the test pads 200 are formed. The thickness T2 along the third direction D3 of each of the second mask patterns MP2 may be less than the thickness T1 along the third direction D3 of each of the first mask patterns MP1. In other words, the second mask patterns MP2 may be formed to have a lesser thickness than the first mask patterns MP1.

Referring to FIGS. 1, 2, and 7, the pad conductive film 140 may be patterned by performing an etching process by using the first mask patterns MP1 and the second mask patterns MP2 as etching masks. Accordingly, the plurality of chip pads CP and the test pads 200 may be formed. The plurality of chip pads CP and the test pads 200 may be simultaneously formed by the etching process, or, alternatively, may be formed in sequential operations. Since the second mask patterns MP2 have a relatively less thickness than the first mask patterns MP1, the second mask patterns MP2 may be removed during the etching process, and thus a portion, of the pad conductive film 140, under the second mask patterns MP2 may be etched. Accordingly, the test pads 200 may be formed to have a lesser thickness than the plurality of chip pads CP. In other words, the thickness 200T along the third direction D3 of each of the test pads 200 may be less than the thickness CP_T along the third direction D3 of each of the plurality of chip pads CP.

According to some example embodiments of the inventive concepts, the plurality of chip pads CP, and the test pads 200 having a lesser thickness than the plurality of chip pads CP may be simultaneously formed by the etching process, or may be formed sequentially.

The plurality of chip pads CP may be formed on each of the plurality of chip regions CR of the substrate 100, and on the interlayer insulating layer 130, and may be spaced apart from each other on the interlayer insulating layer 130 along the first direction D1 and the second direction D2. The test pads 200 may be formed on the interlayer insulating layer 130 on the scribe lane SL, and may be horizontally spaced apart from each other along the first direction D1 or the second direction D2.

According to some example embodiments, additional test patterns 210 may be formed on the interlayer insulating layer 130 on the scribe lane SL, and between the test pads 200. For example, the additional test patterns 210 may be formed by patterning the pad conductive film 140.

Referring back to FIGS. 1 to 3, the passivation layer 150 may be formed on the plurality of chip regions CR and the scribe lane SL of the substrate 100, and on the interlayer insulating layer 130. The passivation layer 150 may be formed to cover the plurality of chip pads CP and the test pads 200. The protective layer 160 may be formed on the plurality of chip regions CR and the scribe lane SL of the substrate 100, and on the passivation layer 150.

Portions of the passivation layer 150 and the protective layer 160 may be removed such that portions of the upper surfaces CP_U of the plurality of chip pads CP and the upper surfaces 200U of the test pads 200 may be exposed. The passivation layer 150 may have (or otherwise define) the first openings 150P respectively exposing portions of the upper surfaces CP_U of the plurality of chip pads CP and the upper surfaces 200U of the test pads 200, and the protective layer 160 may have (or otherwise define) the second openings 160P respectively exposing portions of the upper surfaces CP_U of the plurality of chip pads CP and the upper surfaces 200U of the test pads 200. The second openings 160P may vertically (for example, in the third direction D3) respectively overlap (or at least partially overlap) the first openings 150P. The portions of the upper surfaces CP_U of the plurality of chip pads CP and the upper surfaces 200U of the test pads 200 may be exposed through the first and second openings 150P and 160P.

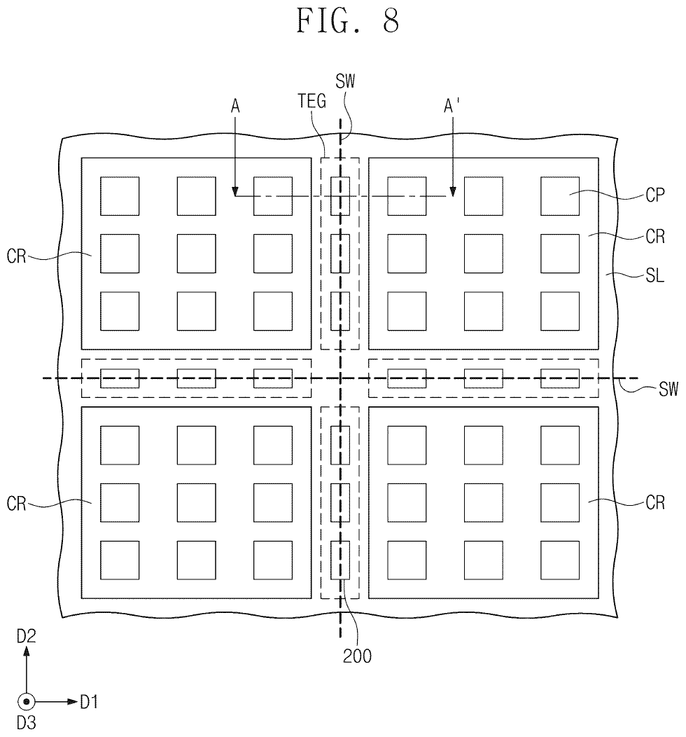

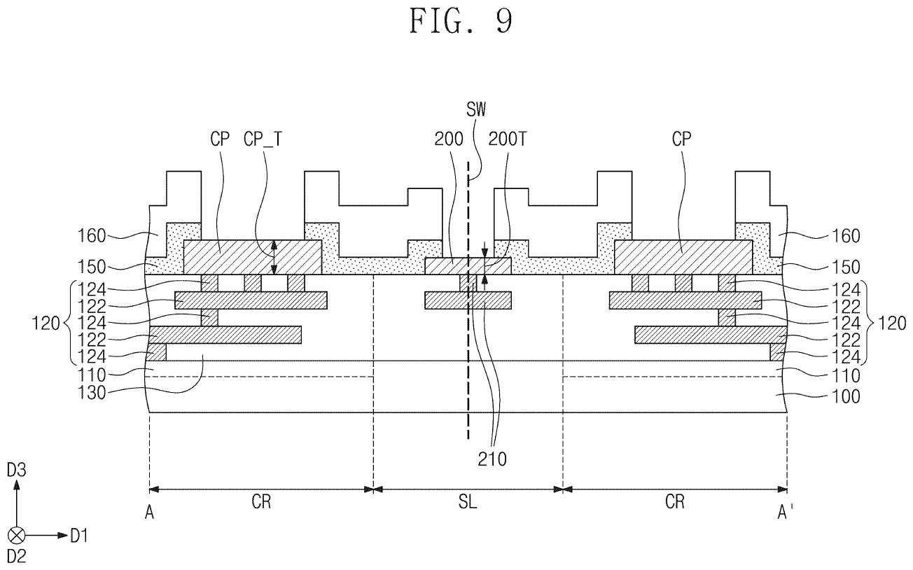

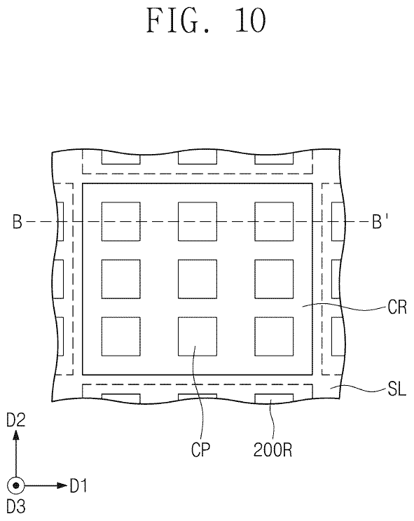

FIG. 8 is a plan view illustrating a method for manufacturing a semiconductor device according to some example embodiments of the inventive concepts, and FIG. 9 is a cross-sectional view taken along A-A′ of FIG. 8.

Referring to FIGS. 8 and 9, the sawing process SW may be performed on the semiconductor device described with reference to FIGS. 1 to 3. The sawing process SW may be performed along the scribe lane SL, and thus the plurality of chip regions CR may be separated into each other. The thickness 200T of the test pads 200 on the scribe lane SL may be less than the thickness CP_T of the plurality of chip pads CP on each of the plurality of chip regions CR, and the test pads 200 may be cut with relative ease during the sawing process SW performed along the scribe lane SL. Accordingly, the plurality of chip regions CR may be separated with relative ease from each other by the sawing process SW, and a plurality of semiconductor chips may be manufactured. The semiconductor chips may each include the chip region CR of the substrate 100, and the integrated circuit layer 110, the circuit wiring layer 120, the interlayer insulating layer 130, the plurality of chip pads CP, the passivation layer 150 and the protective layer 160 formed on the chip region CR.

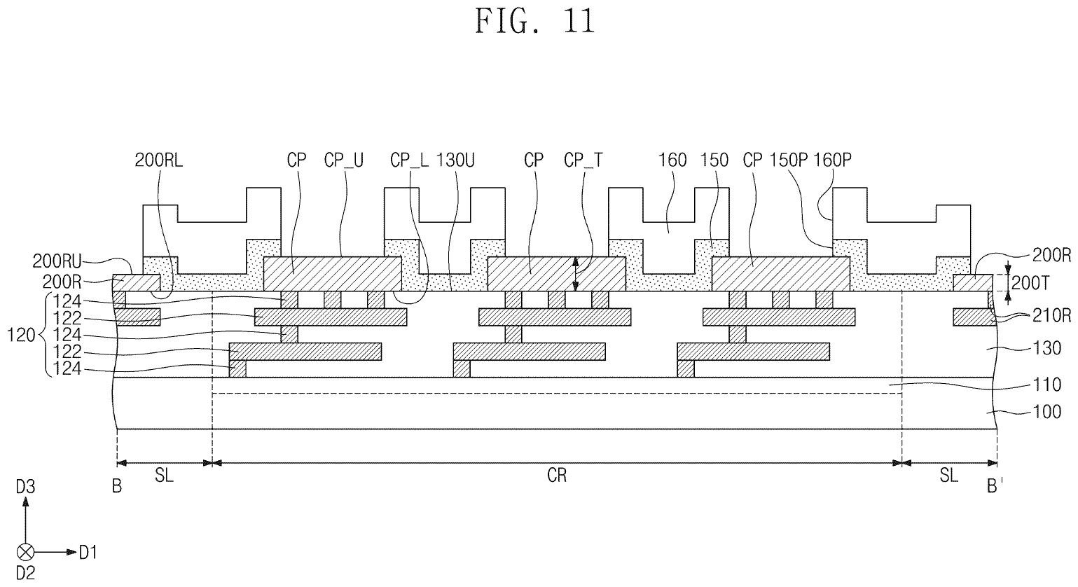

FIG. 10 is a plan view of a semiconductor device according to some example embodiments of the inventive concepts, and FIG. 11 is a cross-sectional view taken along B-B′ of FIG. 10. 1. Elements of the semiconductor device illustrated in FIGS. 10 and 11 may be same as or similar in some respects to the elements of the semiconductor device of FIGS. 1-3, and therefore may be best understood with reference thereto where like numerals indicate like elements not described again in detail. The semiconductor device described with reference to FIGS. 10 and 11 may be referred to as a semiconductor chip.

Referring to FIGS. 10 and 11, the substrate 100 may include the chip region CR and the peripheral region SL. The peripheral region SL may extend along the first direction D1 and the second direction D2, and may surround the chip region CR. The peripheral region SL may be a portion of the scribe lane SL described with reference to FIGS. 1 to 3.

The integrated circuit layer 110 and the circuit wiring layer 120 may be disposed on the chip region CR of the substrate 100. The circuit wiring layer 120 may include the wiring lines 122 and the wiring contacts 124. The circuit wiring layer 120 may be electrically connected to the integrated circuit layer 110. The integrated circuit layer 110 and the circuit wiring layer 120 are described with reference to FIGS. 1 to 3, and a detailed description thereof is omitted herein for the sake of brevity.

The interlayer insulating layer 130 may be disposed on the chip region CR of the substrate 100, and may cover the integrated circuit layer 110 and the circuit wiring layer 120. The interlayer insulating layer 130 may be disposed on the integrated circuit layer 110, and the circuit wiring layer 120 may be disposed in the interlayer insulating layer 130. The interlayer insulating layer 130 may extend on the peripheral region SL of the substrate 100. The interlayer insulating layer 130 is described with reference to FIGS. 1 to 3, and a detailed description thereof is omitted herein for the sake of brevity.

The plurality of chip pads CP may be disposed on the chip region CR of the substrate 100, and on the interlayer insulating layer 130. The plurality of chip pads CP may be spaced apart from each other on the interlayer insulating layer 130 along the first direction D1 and the second direction D2. The circuit wiring layer 120 may be disposed between the integrated circuit layer 110 and the plurality of chip pads CP, and the plurality of chip pads CP may be electrically connected to the integrated circuit layer 110 through the circuit wiring layer 120. The plurality of chip pads CP are described with reference to FIGS. 1 to 3, and a detailed description thereof is omitted herein for the sake of brevity.

The test pads 200 and the test patterns 210 described with reference to FIGS. 1 to 3 may be cut by the sawing process SW that is described with reference to FIGS. 8 and 9, and portions of the test pads 200 and portions of the test patterns 210 may remain on the peripheral region SL of the substrate 100. The remaining portions of the test patterns 210 may be referred to as the remaining test patterns 210R, and the remaining portions of the test pads 200 may be referred to as the remaining test pads 200R. In some example embodiments, the remaining test pads 200R and the remaining test patterns 210R may be disposed on the peripheral region SL of the substrate 100.

The plurality of chip pads CP and the remaining test pads 200R may include a conductive material. The plurality of chip pads CP and the remaining test pads 200R may include the same metal material. The lower surfaces CP_L of the plurality of chip pads CP and lower surfaces 200RL of the remaining test pads 200R may be in contact with the upper surface 130U of the interlayer insulating layer 130. The lower surfaces CP_L of the plurality of chip pads CP and the lower surfaces 200RL of the remaining test pads 200R may be coplanar with the upper surface 130U of the interlayer insulating layer 130, and may be located at the same height (or distance or level) from the substrate 100. Upper surfaces 200RU of the remaining test pads 200R may be located at a different distance from the substrate 100 than upper surfaces CP_U of the plurality of chip pads CP. In some example embodiments, the upper surfaces 200RU of the remaining test pads 200R may be relatively closer (e.g., smaller distance) to the substrate 100 than upper surfaces CP_U of the plurality of chip pads CP.

Each of the plurality of chip pads CP and the remaining test pads 200R may have a thickness along the third direction D3. The thickness 200T along the third direction D3 of each of the remaining test pads 200R may be less than the thickness CP_T along the third direction D3 of each of the plurality of chip pads CP. The thickness CP_T of each of the plurality of chip pads CP may be equal to or greater than 2 μm (or about 2 μm). For example, the thickness CP_T of each of the plurality of chip pads CP may be 2 μm (or about 2 μm) to 5 μm (or about 5 μm). The thickness 200T of each of the remaining test pads 200R may be less than 2 μm (or about 2 μm). For example, the thickness 200T of each of the remaining test pads 200R may be equal to or greater than 1000 Å (0.1 μm) (or about 0.1 μm) and/or less than 2 μm (or about 2 μm).

The passivation layer 150 may be disposed on the chip region CR and the peripheral region SL of the substrate 100, and on the interlayer insulating layer 130. The passivation layer 150 may have (or otherwise define) the first openings 150P respectively exposing portions of the upper surfaces CP_U of the plurality of chip pads CP and portions of the upper surfaces 200RU of the remaining test pads 200R. The protective layer 160 may be disposed on the chip region CR and the peripheral region SL of the substrate 100, and on the passivation layer 150. The protective layer 160 may have (or otherwise define) the second openings 160P respectively exposing portions of the upper surfaces CP_U of the plurality of chip pads CP and portions of the upper surfaces 200RU of the remaining test pads 200R. The second openings 160P may vertically (for example, in the third direction D3) overlap the respective first openings 150P. The passivation layer 150 and the protective layer 160 are described with reference to FIGS. 1 to 3, and a detailed description thereof is omitted herein for the sake of brevity.

According to example embodiments of the inventive concepts, the thickness CP_T of the plurality of chip pads CP may be greater than the thickness 200T of the remaining test pads 200R, and may be equal to or greater than 2 μm (or about 2 μm). Accordingly, bonding strengths between the plurality of chip pads CP and the external connection terminals may be improved or increased.

According to some example embodiments of the inventive concepts, a thickness of a test pad on a peripheral region (or scribe lane) may be less than a thickness of a chip pad on a chip region. Since the test pad has a relatively less thickness, the test pad may be cut with relative ease during a sawing process performed along the peripheral region (or scribe lane). In addition, or alternatively, since the chip pad has a relatively greater thickness, a bonding strength between the chip pad and an external connection terminal may be improved or increased.

Accordingly, a defect that may occur during the sawing process in which a semiconductor substrate is cut may be minimized, and a semiconductor device in which bonding strengths of chip pads of a semiconductor chip may be improved is obtained.

While several example embodiments have been provided in the present disclosure, it should be understood that the disclosed systems and methods might be embodied in many other specific forms without departing from the spirit or scope of the present disclosure. The present examples embodiments are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various example embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A semiconductor device comprising:
a substrate including a chip region and a peripheral region;
a circuit wiring layer on the chip region of the substrate;
an interlayer insulating layer covering the circuit wiring layer on the chip region of the substrate, and extending on the peripheral region of the substrate;
a chip pad on the interlayer insulating layer on the chip region and connected to the circuit wiring layer; and
a test pad on the interlayer insulating layer on the peripheral region, wherein
a thickness of the test pad is less than a thickness of the chip pad in a direction vertical to an upper surface of the substrate.

2. The semiconductor device of claim 1, further comprising:
an integrated circuit layer on the chip region of the substrate, and wherein
the circuit wiring layer is between the integrated circuit layer and the chip pad, and
the chip pad is electrically connected to the integrated circuit layer through the circuit wiring layer.

3. The semiconductor device of claim 1, wherein the chip pad and the test pad comprise a same metal material.

4. The semiconductor device of claim 1, further comprising:
a passivation layer on the interlayer insulating layer on the chip region and at least partially covering the chip pad, and wherein
the passivation layer extends on the interlayer insulating layer on the peripheral region and at least partially covers the test pad, and
the passivation layer defines first openings that expose at least portions of upper surfaces of the test pad and the chip pad.

5. The semiconductor device of claim 4, further comprising:
a protective layer on the passivation layer on the chip region and the peripheral region, and wherein
the protective layer defines second openings that expose at least the portions of the upper surfaces of the chip pad and the test pad, and
the second openings vertically overlap the first openings at least partially.

6. The semiconductor device of claim 1, wherein
a lower surface of the chip pad and a lower surface of the test pad contact an upper surface of the interlayer insulating layer, and
a distance of an upper surface of the test pad from the upper surface of the substrate is less than a distance of an upper surface of the chip pad from the upper surface of the substrate.

7. A semiconductor device comprising:
a substrate including a chip region and a peripheral region;
an integrated circuit layer on the chip region of the substrate;
a circuit wiring layer on the chip region of the substrate and on the integrated circuit layer, the circuit wiring layer being connected to the integrated circuit layer;
an interlayer insulating layer on the chip region of the substrate, the interlayer insulating layer covering the integrated circuit layer and the circuit wiring layer, and extending on the peripheral region of the substrate;
a plurality of chip pads on the interlayer insulating layer on the chip region, and spaced apart from each other in a direction parallel to an upper surface of the substrate; and
a test pad on the interlayer insulating layer on the peripheral region, wherein
the plurality of chip pads are electrically connected to the integrated circuit layer through the circuit wiring layer, and
a thickness of the test pad is less than a thickness of each chip pad of the plurality of chip pads in a direction vertical to the upper surface of the substrate.

8. The semiconductor device of claim 7, wherein the plurality of chip pads and the test pad comprise a same metal material.

9. The semiconductor device of claim 7, further comprising:
a passivation layer on the interlayer insulating layer on the chip region and the peripheral region, and wherein
the passivation layer is between the plurality of chip pads, and between the test pad and the plurality of chip pads.

10. The semiconductor device of claim 9, further comprising:
a protective layer on the passivation layer on the chip region and the peripheral region, and wherein
the protective layer is on the passivation layer between the plurality of chip pads, and on the passivation layer between the test pad and the plurality of chip pads.

11. The semiconductor device of claim 10, wherein at least portions of upper surfaces of the plurality of chip pads are exposed through the passivation layer and the protective layer.

12. The semiconductor device of claim 11, wherein at least a portion of an upper surface of the test pad is exposed through the passivation layer and the protective layer.

13. The semiconductor device of claim 7, wherein
the plurality of chip pads are spaced apart from each other in a first direction and a second direction parallel to the upper surface of the substrate, the first direction and the second direction crossing each other, and
the peripheral region surrounds the chip region in the first direction and the second direction.

14. A semiconductor device comprising:
a substrate including a plurality of chip regions and a scribe lane therebetween;
a circuit wiring layer on each of the plurality of chip regions;
an interlayer insulating layer on each of the plurality of chip regions, the interlayer insulating layer covering the circuit wiring layer and extending on the scribe lane;
a plurality of chip pads on the interlayer insulating layer on each of the plurality of chip regions and spaced apart from each other in a direction parallel to an upper surface of the substrate; and
a test pad on the interlayer insulating layer on the scribe lane, wherein
the plurality of chip pads are electrically connected to the circuit wiring layer, and
a thickness of the test pad is less than a thickness of each chip pad of the plurality of chip pads in a direction vertical to the upper surface of the substrate.

15. The semiconductor device of claim 14, further comprising:
test patterns in the interlayer insulating layer on the scribe lane, and wherein
the test pad is electrically connected to the test patterns.

16. The semiconductor device of claim 14, further comprising:
a passivation layer on the interlayer insulating layer on the plurality of chip regions and the scribe lane, and wherein
the passivation layer defines first openings that expose at least portions of upper surfaces of the plurality of chip pads and at least a portion of an upper surface of the test pad.

17. The semiconductor device of claim 16, wherein the passivation layer covers side surfaces of each of the plurality of chip pads, and partially covers an upper surface of each chip pad of the plurality of chip pads.

18. The semiconductor device of claim 17, further comprising:
a protective layer on the passivation layer on the plurality of chip regions and the scribe lane, and wherein
the protective layer defines second openings that expose at least the portions of the upper surfaces of the plurality of chip pads and at least the portion of the upper surface of the test pad, and
the second openings at least partially overlap the respective first openings in the direction vertical to the upper surface of the substrate.

19. The semiconductor device of claim 18, wherein the protective layer comprises photosensitive polyimide.

20. The semiconductor device of claim 14, wherein the test pad and the plurality of chip pads comprise a same metal material.
